(19) United States
(12) Patent Application Publication
(10) Pub. No.: US 2003/0146673 A1
(43) Pub. Date: Aug. 7, 2003

(54) Ultrasonic touch panel

(76) Inventors: Kouji Toda, Kanagawa (JP); Takafumi Sarata, Chiba (JP); Fumio Kimura, Chiba (JP); Hideki Kitajima, Chiba (JP); Masataka Shinogi, Chiba (JP)

Correspondence Address: Adams & Wilks, 31st Floor, 50 Broadway, New York, NY, 10004, US

(21) Appl. No.: 10/204,728

(22) PCT Filed: Nov. 21, 2001
(86) PCT No.: PCT/JP01/10189

(30) Foreign Application Priority Data
Dec. 1, 2000 (JP) 2000-367565
May 28, 2001 (JP) 2001-159323

(51) Int. Cl. H03H 9/25

(52) U.S. Cl. 310/313 D

(57) ABSTRACT

An ultrasonic touch panel is offered which can detect whether there is a touch, at an improved accuracy without the need to adjust the detection sensitivities of individual piezoelectric bodies separately. The piezoelectric bodies have comb-like electrodes that excite ultrasonic waves. A sealant is applied to those of the side surfaces of the piezoelectric bodies which intersect with the direction of propagation of the excited ultrasonic waves. This suppresses reflection of the ultrasonic waves, thus attenuating ultrasonic waves propagating to the intersecting side surfaces. Generation of parasitic waves which would normally be caused by reflection of ultrasonic waves is prevented.

### TECHNICAL FIELD

This invention relates to an ultrasonic touch panel used in mobile devices, electronic notes, or various kinds of display devices.

### BACKGROUND ART

A conventional touch panel using ultrasonic waves comprises a nonpiezoelectric substrate and piezoelectric bodies mounted to the nonpiezoelectric substrate.

The structure of the conventional ultrasonic touch panel is described by referring to the perspective view of FIG. 13. The nonpiezoelectric substrate 1 is rectangular in shape, and the plural piezoelectric bodies 2 are fixedly mounted on the nonpiezoelectric substrate 1. Comb-like electrodes are formed on the surface of each piezoelectric body 2. The cross-sectional shape of each piezoelectric body 2 used conventionally is described by referring to FIG. 14, which is a cross-sectional view taken along a dot-and-dash line in FIG. 13. Side surfaces 3 of the piezoelectric body 2 are perpendicular to the surface of the nonpiezoelectric substrate 1 and to the top and bottom surfaces of the piezoelectric body 2.

Each piezoelectric body 2 is so orientated that the comb-like electrodes face normal to the direction of propagation of ultrasonic waves. As one example of the arrangement, two piezoelectric bodies 2 are arranged opposite to each other such that their comb-like electrodes are parallel to each other, as shown in FIG. 13. A voltage is applied to the comb-like electrodes of one piezoelectric body 2. This excites ultrasonic waves via piezoelectric effects. The acoustic waves propagate on the nonpiezoelectric substrate and are received by the other piezoelectric body 2. The acoustic waves are delivered as an electrical signal. This structure having send/receive functions and acting to propagate ultrasonic waves is regarded to have the function of a bandpass filter as viewed electrically. Therefore, a maximum output voltage is obtained at a certain frequency determined by the length of the period of the comb-like electrodes.

When load is applied to the nonpiezoelectric substrate 1 as encountered when a finger touches it, the intensity of acoustic waves attenuates at the load location. Therefore, the intensity of the received acoustic waves decreases, resulting in a decrease in the output voltage of the electrical signal. A threshold value is set for the output voltage. A touch on the touch panel is detected when the output voltage decreases below the threshold voltage.

Where the side surfaces of each piezoelectric body are perpendicular to the top surface as mentioned previously, acoustic waves are reflected at the side surfaces of the piezoelectric body. This induces different modes of oscillations, producing parasitic waves.

Portions where the piezoelectric bodies are adhesively bonded to the top surface of the nonpiezoelectric substrate include corner portions formed by intersection of the side surfaces of the piezoelectric bodies and the top surface of the nonpiezoelectric substrate. These corner portions reflect acoustic waves, inducing various modes of oscillations. This may produce parasitic waves.

The parasitic waves described above have different phases with respect to propagating acoustic waves. Therefore, the parasitic waves interfere with the propagating acoustic waves, producing the effect that the amplitude is varied. That is, acoustic waves propagating from the sending piezoelectric body to the nonpiezoelectric substrate and acoustic waves propagating from the nonpiezoelectric substrate to the receiving piezoelectric body interfere with the parasitic waves, thus producing complex waveforms. Therefore, the output electrical signal that is produced by receiving the propagating acoustic waves by means of the receiving piezoelectric body is complex. This makes it difficult to control to detect whether there is a touch on the nonpiezoelectric substrate, which leads to a decrease in the detection accuracy.

Furthermore, interference with the parasitic waves modulates the amplitude of the propagating acoustic waves. Consequently, the intensity varies from location to location on the nonpiezoelectric substrate. Hence, the sensitivity varies from location to location even in an ultrasonic region to which acoustic waves are transmitted from one piezoelectric body.

In addition, the plural piezoelectric bodies are securely fixed, mounted to the substrate, sealed, and otherwise treated. Therefore, ultrasonic excitation mode and reflection of ultrasonic waves differ among the individual piezoelectric bodies. In consequence, the intensity of received ultrasonic waves differs among the individual piezoelectric bodies. This makes the output voltage versatile. Accordingly, it is necessary to set threshold values for the output voltages of individual piezoelectric bodies or to adjust the detection sensitivities of the individual piezoelectric bodies by adding a compensation circuit or log amplifiers. This will increase the number of fabrication steps and power consumption.

The present invention is intended to solve the problems described thus far.

### DISCLOSURE OF THE INVENTION

The above-described problems are solved in accordance with the teachings of the prevent invention by an ultrasonic touch panel having piezoelectric bodies each fitted with comb-like electrodes and a nonpiezoelectric substrate having one surface to which the piezoelectric bodies are fixedly mounted, the piezoelectric bodies having a function of sending and receiving ultrasonic waves. The comb-like electrodes are formed either on fixedly mounted surfaces (hereinafter referred to as the bottom surfaces) of the piezoelectric bodies mounted on the nonpiezoelectric substrate or on the surfaces (hereinafter referred to as the top surfaces) of the piezoelectric bodies opposite to the bottom surfaces of the piezoelectric bodies. The two piezoelectric bodies are placed opposite to each other. The side surfaces of each piezoelectric body include two opposite side surfaces a and b intersecting with propagation path for ultrasonic waves excited by the comb-like electrodes. This touch panel is characterized in that a structure for attenuating the ultrasonic waves is formed on any one or both of these side surfaces a and b. The structure also suppresses reflection of the ultrasonic waves at the side surface or surfaces.

Thus, reflection of ultrasonic waves at the side surfaces of the piezoelectric bodies is suppressed, producing less parasitic waves. Therefore, the main component of ultrasonic waves propagating on the nonpiezoelectric substrate is ultrasonic waves having a certain frequency determined by the length of the period of the comb-like electrodes. As a result, the output electrical signal is simplified. The output signals from the individual piezoelectric bodies are made uniform. Furthermore, the sensitivity is made uniform over the surface of the nonpiezoelectric substrate. Accordingly, the threshold value for the output voltage can be easily set. It is easier to provide control to detect whether there is a touch on the nonpiezoelectric substrate. Hence, the detection accuracy is improved. The power consumption decreases. The number of fabrication steps can be reduced.

As one example of the structure for suppressing reflection of ultrasonic waves, structures capable of absorbing ultrasonic waves are firmly mounted to the side surfaces a and b.

Since ultrasonic waves propagate to these structures and attenuate within them, the situation is as if the acoustic waves were absorbed. As a result, ultrasonic waves are not reflected at the side surfaces a and b and so parasitic waves are produced less easily.

The structures consist of resilient bodies. Thus, ultrasonic waves are absorbed irrespective of the shape of the resilient bodies. Accordingly, it is only required to fixedly mount the resilient bodies in forming the structures. This produces the advantage that the number of steps is reduced.

A sealant for sealing the side surfaces of the resilient bodies is applied. This makes it easy to apply the sealant to the side surfaces of the piezoelectric bodies with a dispenser. Consequently, the structures can be formed readily.

The sealant applied to the side surface b is integrally applied on a circuit board that is electrically connected with the comb-like electrodes.

In this way, reflection of ultrasonic waves at the side surface is suppressed. At the same time, either the circuit board and the nonpiezoelectric substrate or the piezoelectric bodies can be adhesively mounted. In addition, where the electrical connection is made by wire bonding or using leads, the electrically connected portions on the circuit board can be sealed. Therefore, the mechanical strength of the electrically connected portions is increased compared with the case where the sealant is not present. The effects of the external environment can be reduced.

In addition, the circuit board may be made of a flexible printed circuit. The circuit board is connected either with the comb-like electrodes formed on the top surfaces of the piezoelectric bodies or with terminal electrodes that are at the same potential as the comb-like electrodes. Then, the circuit board is fixedly mounted.

The sealant is applied to the piezoelectric bodies and to the flexible printed circuit, thus increasing their mounting strength. The flexible printed circuit does not easily peel off from the piezoelectric bodies. Furthermore, the flexible printed circuit is less likely to bend at the portions to which the sealant has been applied. As a consequence, the conductors on the flexible printed circuit can be prevented from breaking due to bending.

Alternatively, the resilient bodies are made of rubber. The intensity of propagating ultrasonic waves is attenuated by the rubber-like resilience. Therefore, ultrasonic waves can be absorbed more effectively. In addition, because of the high elastic modulus of the resilient rubber, a structure that is highly durable to external shocks is obtained.

As one structure for suppressing reflection of ultrasonic waves, any one or both of the side surfaces a and b described above are formed as inclined surfaces.

Thus, as ultrasonic waves reaching the side surfaces of the piezoelectric bodies propagate along the inclined surfaces, the waves are attenuated. As a result, the strength becomes minimal at the front ends of the inclined surfaces. Reflections are prevented. Accordingly, parasitic waves are less easily produced at the side surfaces of the piezoelectric bodies.

The cross-sectional shape of the side surfaces of the piezoelectric bodies is hereinafter described.

With respect to the shape of the inclined surfaces, the cross-sectional shape of the piezoelectric bodies is formed as a straight line at the side surfaces of the piezoelectric bodies. The angle made between the top surface of each piezoelectric body and each side surface is set to an obtuse angle.

The result is that parasitic waves are less easily produced on the side surfaces of the piezoelectric bodies.

Alternatively, with respect to the shape of the tilted surfaces, the cross-sectional shape of the piezoelectric bodies is a concave curved line at the side surfaces of the piezoelectric bodies. The angle made between the top surface of each piezoelectric body and each side surface is set to an obtuse angle.

As a result, parasitic waves are less easily produced on the side surfaces of the piezoelectric bodies. The junction area between each of the piezoelectric bodies and the nonpiezoelectric substrate is increased. Hence, the bonding strength can be increased.

Alternatively, with respect to the shape of the tilted surfaces, the cross-sectional shape of the piezoelectric bodies is a concave curved line at the side surfaces of the piezoelectric bodies. The angle made between the top surface of each of piezoelectric bodies and each side surface is set to an acute angle.

Consequently, parasitic waves are less easily produced on the side surfaces of the piezoelectric bodies. During fabrication of the touch panel, when the piezoelectric bodies and the nonpiezoelectric substrate are bonded firmly, gas may be sealed in the firmly bonded portions. When ultrasonic waves are propagating, the acoustic waves are disturbed by the air layer. However, this shape reduces the junction area between the nonpiezoelectric substrate and each of the piezoelectric bodies. As a result, the amount of the produced air layer can be reduced.

Alternatively, with respect to the shape of the inclined surfaces, the cross-sectional shape of the piezoelectric bodies is a straight line at the side surfaces of the piezoelectric bodies. The angle made between the top surface of each piezoelectric body and each side surface is set to an acute angle.

As such, parasitic waves are less easily produced on the side surfaces of the piezoelectric bodies. Also, the junction area between the nonpiezoelectric substrate and each of the piezoelectric bodies decreases. Therefore, during fabrication of the touch panel, the amount of the air layer in the fixedly mounted portions decreases. Furthermore, the comb-like electrodes can be fabricated over the whole top surfaces of the piezoelectric bodies. If the number of comb-like electrodes is increased compared with other structures, it is not necessary to increase the area on the nonpiezoelectric substrate occupied by the piezoelectric bodies. Therefore, a transducer having a high ultrasonic conversion efficiency can be fabricated with a reduced area.

Further, with respect to the shape of the tilted surface, the corner portions formed between the side surfaces of the piezoelectric bodies and the bottom surfaces of the piezoelectric bodies are arc-shaped forms. At the portions where the piezoelectric bodies and the top surface of the nonpiezoelectric substrate are adhesively bonded together, the top surface of the nonpiezoelectric substrate is formed as a tangential plane to lower portions of the side surfaces a and b.

As a result, no corner portions are formed at the portions where the piezoelectric bodies and the top surface of the nonpiezoelectric substrate are adhesively bonded together. Ultrasonic waves propagating from the piezoelectric bodies to the nonpiezoelectric substrate have heretofore tended to induce parasitic waves at the corner portions. The present shape suppresses parasitic waves.

As a structure for suppressing reflection of ultrasonic waves, a thin metal sheet having a height equivalent to the height of the piezoelectric bodies is firmly mounted to the side surfaces a and b. Of two opposite surfaces c and d of the thin metal sheet, the surface d opposite to the firmly mounted surface c with the piezoelectric body is formed as an inclined surface.

Because of the matching of acoustic impedance between each piezoelectric body and the thin metal sheet, ultrasonic waves are not easily reflected off the interface between the piezoelectric body and the thin metal sheet, and parasitic waves are not easily produced at this interface where they are firmly bonded together. Propagation of ultrasonic waves from the piezoelectric body to the thin metal sheet is smoothly effected without producing reflected waves or parasitic waves. Therefore, generation of reflected waves or parasitic waves at the side surface d of the thin metal sheet can be suppressed by providing the structure for attenuating ultrasonic waves to the side surface d of the thin metal sheet.

The cross-sectional shape of the side surface d of the thin metal sheet is hereinafter described.

With respect to the cross-sectional shape of the thin metal sheet, the shape is a straight line on the side surface d. The angle made between the top surface of each piezoelectric body and the side surface is set to an obtuse angle.

As a result, parasitic waves are less easily produced on the side surface of the piezoelectric body. Since the side surface of the piezoelectric body is not machined, it is easy to fabricate the structure for suppressing reflection.

Alternatively, the cross-sectional shape of the thin metal shape may be a concave curved line at the side surface d, and the angle made between the top surface of each piezoelectric body and the side surface may be set to an obtuse angle.

Thus, parasitic waves are not produced easily on the side surface of the piezoelectric body. Furthermore, the cross-sectional shape is a concave curve line and so it is easy to control the shape during fabrication. The quality is stabilized.

Alternatively, the cross-sectional shape of the thin metal shape may be a straight line or concave curved line at the side surface d, and the angle made between the top surface of each piezoelectric body and the side surface may be set to an acute angle.

In this way, parasitic waves are less easily produced at the side surface of the piezoelectric body. Furthermore, the area of the joint portion between the nonpiezoelectric substrate and the thin metal sheet decreases. Consequently, reflection of ultrasonic waves at the joint portion and generation of parasitic waves can be reduced.

In addition, the corner portion made between the side surface d and the bottom surface of each piezoelectric body is an arc-shaped form. Therefore, at the portion where the thin metal sheet and the top surface of the nonpiezoelectric substrate are adhesively bonded together, the top surface of the nonpiezoelectric substrate is a tangential plane to the lower portion of the side surface d of the thin metal sheet.

Thus, no corner portion is formed at the bonding portion between the thin metal sheet and the top surface of the nonpiezoelectric substrate. In consequence, parasitic waves which would have been conventionally induced by the corner portion are not produced.

A method of fabricating the structure for suppressing reflection of ultrasonic waves as described thus far is hereinafter described.

The fabrication method is used to fabricate an ultrasonic touch panel consisting of piezoelectric bodies, a nonpiezoelectric substrate, and a printed circuit board. Each of the piezoelectric bodies has comb-like piezoelectric body. The piezoelectric bodies are firmly mounted on one surface of the nonpiezoelectric substrate. The two piezoelectric bodies are placed opposite to each other. This method includes a step of applying a sealant to a side surface b of each piezoelectric body which is opposite to a side surface a of the piezoelectric body. These side surfaces a and b intersect with the propagation path for ultrasonic waves excited by the comb-like electrodes. This step of applying a sealant consists of firmly mounting the piezoelectric bodies and the nonpiezoelectric substrate, connecting the comb-like electrodes and terminal electrodes at the same potential as the comb-like electrodes with a pattern on the printed circuit board and firmly fixing them, and injecting the sealant into the corner portion made between the side surface b and the printed circuit board.

Thus, the structure for suppressing reflected waves by sealing the side surface b and high bonding strength between the non piezoelectric substrate or each piezoelectric body and the printed circuit board are obtained simultaneously. The sealant is applied after the piezoelectric bodies are firmly mounted to the nonpiezoelectric substrate. Therefore, the sealant can be applied to the plural piezoelectric bodies at a time, using a dispenser.

Then, a step consisting of applying the sealant to the side surface a to form the sealant on this side surface a is carried out.

In this manner, structures for suppressing reflected waves can be formed on the side surfaces a of the plural piezoelectric bodies at a time. In addition, waterproofness can be given.

The step of obtaining the piezoelectric bodies or the side surface structures of the thin metal sheet described above and the step of cutting the piezoelectric bodies or the thin metal sheet are carried out in one step.

Thus, structures capable of suppressing reflected waves efficiently can be fabricated without increasing the number of process steps.

In particular, the side surface structure (i.e., the cross-sectional shape at the side surface is a straight line), can be fabricated simultaneously with cutting the piezoelectric bodies or thin metal sheet along the oblique side of a blade whose height is greater than the height of the piezoelectric bodies in the cross-sectional shape at the edge of the blade.

Furthermore, the side surface shape (i.e., the cross-sectional shape of the side surface is a concave curved line) is formed by cutting the piezoelectric bodies or the thin metal sheet with a blade having an edge whose cross-sectional shape is an R-shaped form, such that the tip of the blade is at a height equivalent to the height of the bottom surfaces of the piezoelectric bodies or the thin metal sheet.

This side surface shape can be obtained easily in this way. Since formation of the side surface shape using such cutting and extraction of the shape from a base material for application of the piezoelectric bodies to a touch panel can be carried out simultaneously, there is the advantage that it is not necessary to increase the number of process steps. Where the angle made between the top surface of each piezoelectric body and the side surface is an obtuse angle, the side surface structure can be formed after firmly mounting the piezoelectric bodies or the thin metal sheet to the nonpiezoelectric substrate, for the following reasons. The piezoelectric bodies arranged in a line or plural such thin metal sheets can be molded simultaneously and so the plural piezoelectric bodies or thin metal sheets can be placed without position deviation. After forming the side surface shape, there is no process step where load is applied to the side surface. Therefore, the side surface does not crack nor break. The side surface shape can be retained stably.

Furthermore, fabrication of the side surface shape is carried out by firmly mounting the piezoelectric bodies or the thin metal sheet to the nonpiezoelectric substrate and adding a metal or metal compound to the corner portion made between the side surface and the nonpiezoelectric substrate to form a molded body having an oblique side shape.

This makes it possible to form the molded body having the oblique side structure with high intimate force without machining the piezoelectric bodies or the thin metal sheet at all. Therefore, the characteristics of the piezoelectric bodies are prevented from being impaired. Since the molded body is a metal or metal compound, the matching of acoustic impedance with the piezoelectric bodies or thin metal sheet is high. Ultrasonic waves can be efficiently propagated to the flame-sprayed, molded body from the piezoelectric bodies or thin metal sheet.

Flame spraying is used to add the metal or metal oxide to the side surface.

Consequently, a molded body having an oblique side structure that makes intimate contact with the piezoelectric bodies or thin metal sheet can be fabricated.

The step of adding the metal or metal oxide to the side surface consists of applying a metal braze material or melted metal and solidifying the metal.

Thus, it is easy to control the shape of the molded body and the position where it is formed. Furthermore, the molded body that makes intimate contact with the piezoelectric bodies or thin metal sheet can be fabricated. Since the molded body is a metal, the matching of acoustic impedance with the piezoelectric bodies or thin metal sheets is high. Ultrasonic waves from the piezoelectric bodies or thin metal sheets can be propagated efficiently to the flame-sprayed, molded body.

In the method of forming the oblique side as described thus far, where the angle made between the top surface of each piezoelectric body and the side surface is an obtuse angle, the following method can be adopted. A structure whose oblique side is placed on the side of each piezoelectric body. The angle made between the top surface and the oblique side is an obtuse angle. This structure is firmly mounted to the nonpiezoelectric substrate. The metal is applied to the side surface of the piezoelectric body and to the structure and hardened.

As a result, reflection of ultrasonic waves at the side surface of the piezoelectric body is suppressed. Generation of parasitic waves can be suppressed. Therefore, it is easy to provide control regarding detection to know whether there is a touch on the ultrasonic touch panel. The intensities of ultrasonic waves within the plane of the nonpiezoelectric substrate are made uniform. The output voltage is regulated. A touch panel having fewer malfunctions can be offered without adjusting the detection sensitivities of the individual piezoelectric bodies.

### BRIEF DESCRIPTION OF THE DRAWINGS

FIG. 1 is a cross-sectional view of a touch panel according to Embodiment 1 of the present invention;

FIG. 2 is a cross-sectional view of a touch panel which is according to Embodiment 1 of the invention but different in structure with the touch panel of FIG. 1;

FIG. 3 is a diagram showing the I/O efficiency of the prior art ultrasonic touch panel at frequencies of 6 to 7 MHz;

FIG. 4 is a diagram showing the I/O efficiency of the ultrasonic touch panel of FIG. 1 at frequencies of 6 to 7 MHz;

FIG. 5 is a cross-sectional view of a touch panel according to Embodiment 1 of the invention, and in which a circuit board and piezoelectric bodies have been connected together by wire bonding;

FIG. 6 is a cross-sectional view of a touch panel according to Embodiment 2 of the invention;

FIG. 7 is a cross-sectional view of a touch panel according to Embodiment 3 of the invention, and in which the angle made between the top surface of each piezoelectric body and a side surface of the piezoelectric body is an obtuse angle;

FIG. 8 is a cross-sectional view of a touch panel according to Embodiment 3 of the invention, and in which the angle made between the top surface of a piezoelectric body and a side surface of the piezoelectric body is an acute angle;

FIG. 9 is a cross-sectional view of a touch panel according to Embodiment 3 of the invention, and in which the angle made between the top surface of each piezoelectric body and a side surface of the piezoelectric body is an acute angle, the side surface being a concave curved surface;

FIG. 10 is a cross-sectional view of a touch panel according to Embodiment 3 of the invention, and in which the top surface of each nonpiezoelectric substrate is a tangential plane to the lower portion of the side surface;

FIG. 11 is a cross-sectional view of a touch panel according to Embodiment 4 of the present invention;

FIG. 12 is a cross-sectional view of a touch panel which is according to Embodiment 4 of the invention but different in structure with the touch panel of FIG. 10;

FIG. 13 is a perspective view of a conventional touch panel; and

FIG. 14 is a cross-sectional view of the conventional touch panel.

### BEST MODE FOR CARRYING OUT THE INVENTION

In order to describe the present invention in further detail, various embodiments of the present invention are described with reference to the accompanying drawings.

[Embodiment 1]

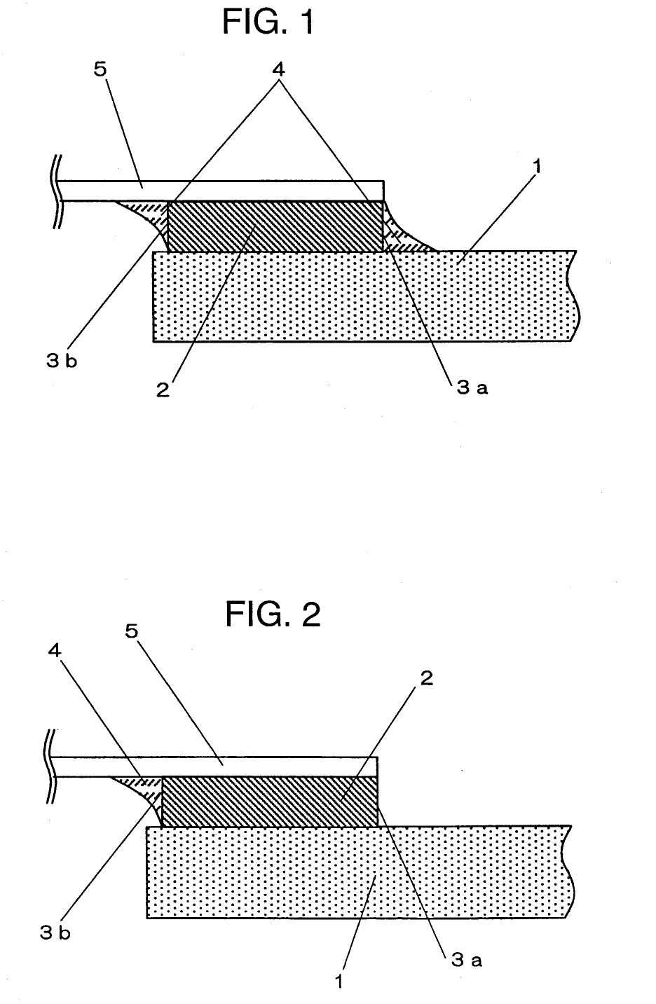

FIGS. 1 and 2 are cross-sectional views of the vicinities of piezoelectric bodies placed on a touch panel according to the present invention. The cross-sectional views are taken along the direction of propagation of ultrasonic waves. Each piezoelectric body, 2, is firmly mounted on a rectangular, nonconducting, nonpiezoelectric substrate 1. A circuit board 5 is electrically connected with comb-like electrodes and securely mounted on the top surface of each piezoelectric body 2. A flexible printed circuit having high flexibility is used as the circuit board 5. In FIG. 1, a sealant 4 for sealing side surfaces 3 is provided, the side surfaces 3 intersecting with the direction of propagation of ultrasonic waves excited by the comb-like electrodes. The sealant 4 on the side surface 3b of the piezoelectric body 2 opposite to the side surface 3a is on the corner portion between the circuit board 5 and the side surface 3b. In FIG. 2, the sealant 4 is applied to the side surface 3b and to the circuit board 5.

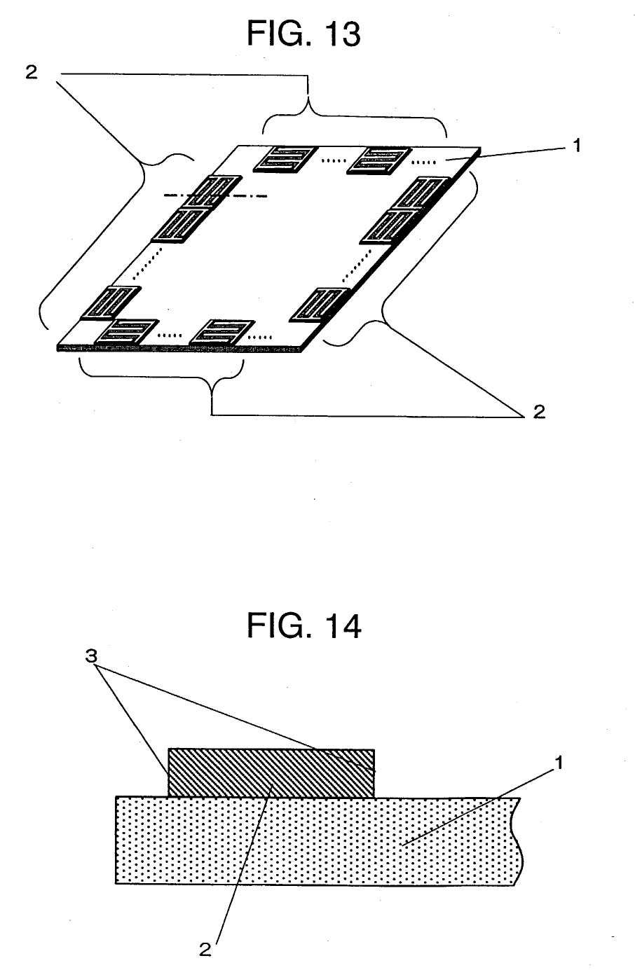

The method of arranging the nonpiezoelectric substrate 1 and the piezoelectric bodies 2 of the touch panel according to the present invention is the same as the conventional method. That is, as shown in the perspective view of FIG. 13, the piezoelectric bodies 2 on which the comb-like electrodes are formed on the rectangular, nonconducting, non piezoelectric substrate 1 are firmly mounted along the sides of the nonpiezoelectric substrate 1. The piezoelectric bodies 2 are so arranged that the comb-like electrodes face normal to the direction of propagation of ultrasonic waves. The operation of the touch panel of the present invention has been already described in the means for solving the problems.

The touch panel described thus far is manufactured in the manner described below. As a first step, the piezoelectric bodies 2 are firmly mounted on the nonpiezoelectric substrate 1 along the sides of the nonpiezoelectric substrate 1. As a second step, the comb-like electrodes formed on the top surfaces of the piezoelectric bodies 2 and the pattern of the circuit board 5 are heated and pressed together using an anisotropic conductive film. Then, they are electrically connected. As a third step, an UV-curable sealant 4 is injected into the corner portion between the side surface 3b and the circuit board 5 by a dispenser, applied there, and UV cured. Referring still to FIG. 1, as a fourth step, the sealant 4 is applied also to the side surface 3a and UV cured.

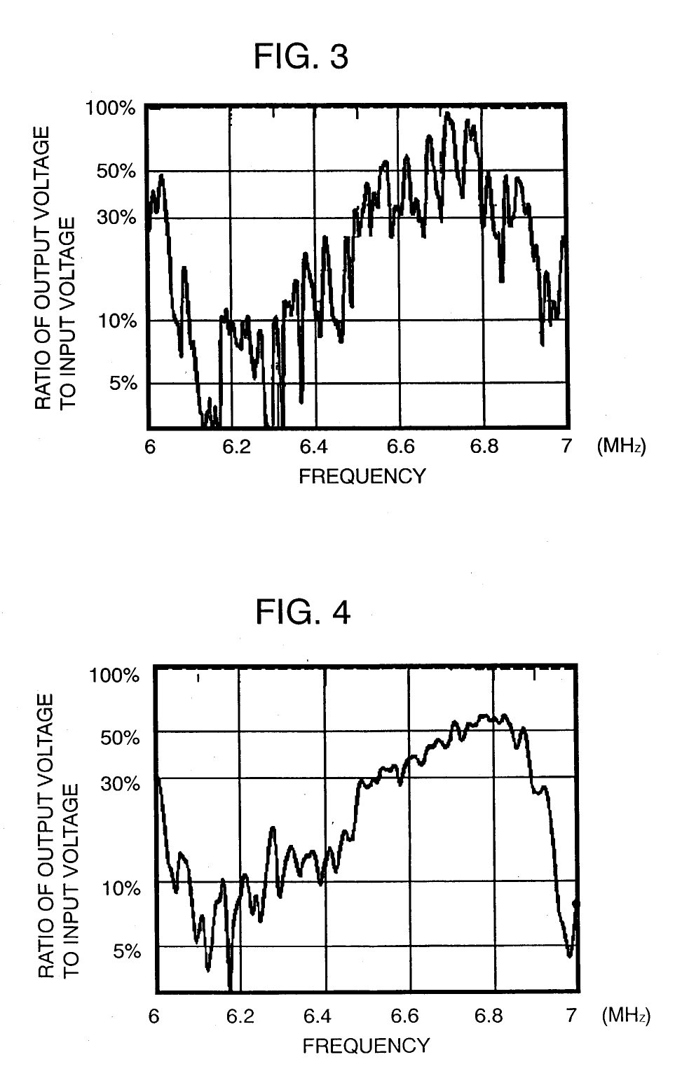

The results of measurements of the I/O efficiency of the ultrasonic touch panel at frequencies of 6 to 7 MHz are shown in FIGS. 3 and 4. Frequency is plotted on the horizontal axis, while the ratio of the output voltage to the input voltage is plotted on the vertical axis. FIG. 3 shows a case of the conventional system of FIG. 14 where the sealant 4 is not used. FIG. 4 shows a case of the structure shown in FIG. 1. The curved line of FIG. 4 is smoother (i.e., less uneven) than the curved line of FIG. 3. The unevenness is attributed to parasitic waves. It can be said that the sealant 4 that seals the side surfaces 3 suppresses generation of parasitic waves in the case of FIG. 1. Similar but somewhat inferior effects are obtained in the case of FIG. 2.

As a result, such an influence that it is difficult to provide control to know whether there is a touch on the nonpiezoelectric substrate 1 is vanished. Variations in the intensity of ultrasonic waves within the plane of the nonpiezoelectric substrate decrease, so that the output voltage is regulated. The detection sensitivities of individual piezoelectric bodies are not adjusted separately. Fewer malfunctions occur. The detection accuracy can be improved.

At the same time, the sealant 4 on the side surface 3b prevents bending of the circuit board 5 and so breaks in lines of the pattern on the circuit board 5 can be prevented. Furthermore, the sealant 4 prevents the piezoelectric bodies 2 from being exposed to the outside. Consequently, the piezoelectric bodies 2 are protected from the ambient environment (e.g., moisture and chemicals). In this advantage, the structure of FIG. 1 where the sealant 4 is applied to both side surfaces 3a and 3b is superior to the structure of FIG. 2.

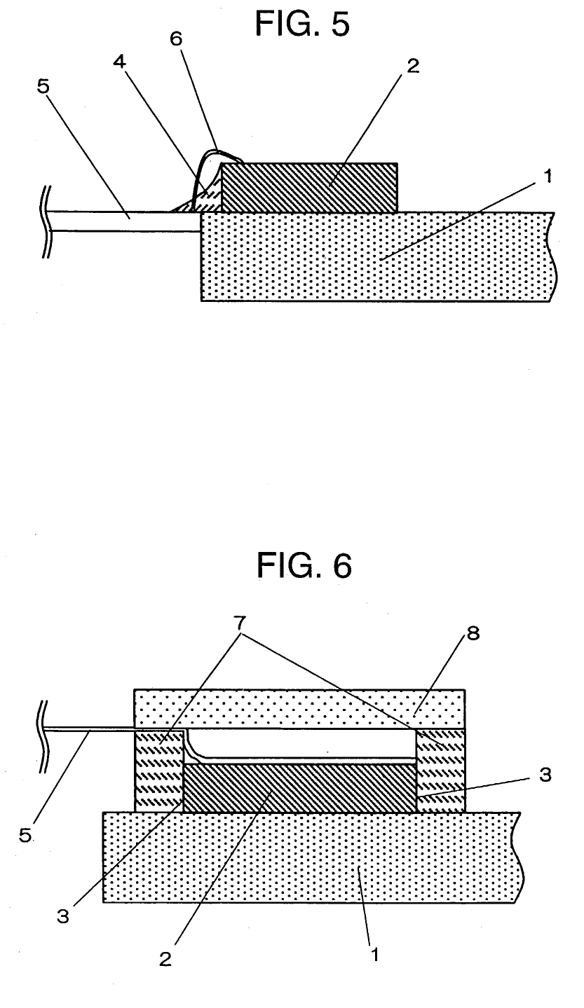

An example where the circuit board 5 is placed around the nonpiezoelectric substrate 1 is shown in FIG. 5. This example produces the same effect of suppressing reflected waves and parasitic waves as FIG. 2. In this case, however, the pattern on the circuit board 5 is connected with the comb-like electrodes by wire bonding in the second step described above. The sealant 4 on the side surface 3b suppresses reflected waves and, at the same time, adhesively bonds together the nonpiezoelectric substrate 1 and the circuit board 5. Furthermore, there is the advantage that the bonding wire 6 on the circuit board 5 is sealed, thus enhancing the connection reliability.

[Embodiment 2]

FIG. 6 is a cross-sectional view of the vicinities of piezoelectric bodies arranged on a touch panel according to the present invention. This cross-sectional view is taken along the direction of propagation of ultrasonic waves. Piezoelectric bodies 2 are firmly mounted on a rectangular, nonconducting, nonpiezoelectric substrate 1. A circuit board 5 is electrically connected with comb-like electrodes on the top surfaces of the piezoelectric bodies 2 and securely mounted. A flexible printed circuit of high flexibility is used as the circuit board 5. Resilient rubber 7 is securely mounted to side surfaces 3 intersecting with the direction of ultrasonic waves excited by the comb-like electrodes. Two masses of resilient rubber 7 are placed over the top surface of each piezoelectric body 2 such that the piezoelectric body 2 is sandwiched between the two masses of resilient rubber 7. A metal cover 8 is bridged across the two masses of resilient rubber 7. The nonpiezoelectric substrate 1 and the piezoelectric bodies 2 of the touch panel according to the present invention are arranged by the same method as the prior art method.

Ultrasonic waves propagated to the side surfaces of the piezoelectric body 2 propagate to the resilient rubber 7 and attenuate. Therefore, generation of reflection waves and parasitic waves at the side surfaces 3 is suppressed. Interference with the propagating ultrasonic waves decreases.

The cover 8 mounted in the present example is intended to protect the piezoelectric bodies 2 against shocks and friction and from the ambient environment and to provide noise shielding. In the present example, the resilient rubber 7 is higher than the piezoelectric bodies 2 by 0.5 mm and, therefore, a space is formed between the top surface of each piezoelectric body 2 and the cover 8. Especially, the resilient rubber 7 acts to absorb shocks from the outside.

In this way, the resilient rubber 7 can be used as members which not only suppress generation of parasitic waves but form structures protecting the piezoelectric bodies 2. An equipotential signal produced by the comb-like electrodes does not adversely affect other piezoelectric bodies 2, because the cover 8 acts as a shield preventing noise.

[Embodiment 3]

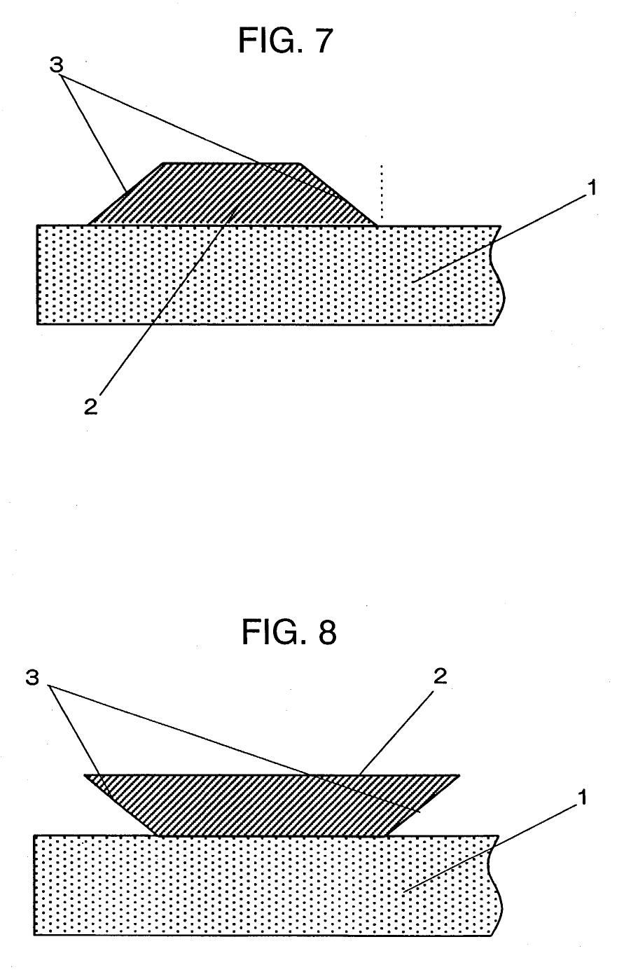

FIG. 7 is a cross-sectional view of the vicinities of piezoelectric bodies arranged on a touch panel according to the present invention. This cross-sectional view is taken along the direction of propagation of ultrasonic waves. Each piezoelectric body 2 having side surfaces 3 consisting of oblique sides is firmly mounted on a rectangular, nonconducting, nonpiezoelectric substrate 1. The angle made between the top surface of the piezoelectric body 2 and each side surface 3 is an obtuse angle.

The method of arranging the nonpiezoelectric substrate 1 and the piezoelectric bodies 2 of the touch panel according to the present invention is the same as the conventional method. The operation of the touch panel of the present invention has been already described in the means for solving the problems.

The side surfaces 3 are shaped simultaneously with extracting the piezoelectric bodies 2 from a piezoelectric sheet with a dicing saw. In particular, the piezoelectric sheet is mounted to the dicing saw, and then the bottom surface of the piezoelectric sheet is placed at a height equivalent to the height of the tip of the blade. Then, cutting is done. At this time, the shape of the tip of the used blade is an oblique side. Therefore, the side surfaces 3 are formed simultaneously with extraction of the piezoelectric bodies 2 of a given size.

FIG. 8 is a cross-sectional view taken along the dot-and-dash line of FIG. 13, and shows piezoelectric bodies 2 having oblique sides different in orientation from those of FIG. 7. With respect to the orientations of the oblique sides, the angle made between the top surface of each piezoelectric body 2 and each side surface 3 is an acute angle. The cross sections of the oblique sides are straight lines.

The side surfaces 3 are formed by the same method as in the case of FIG. 7. However, the direction in which the piezoelectric bodies 2 are mounted is inverted with respect to the case of FIG. 7. Therefore, the bottom surface of each piezoelectric body 2 is smaller in area than the top surface. Accordingly, the area of the portion of the piezoelectric body 2 firmly mounted to the nonpiezoelectric substrate 1 is smaller than in the case of FIG. 7. Since the comb-like electrodes are formed on the top surface, a transducer having a high ultrasonic conversion efficiency can be fabricated on the nonpiezoelectric substrate 1 with a reduced area.

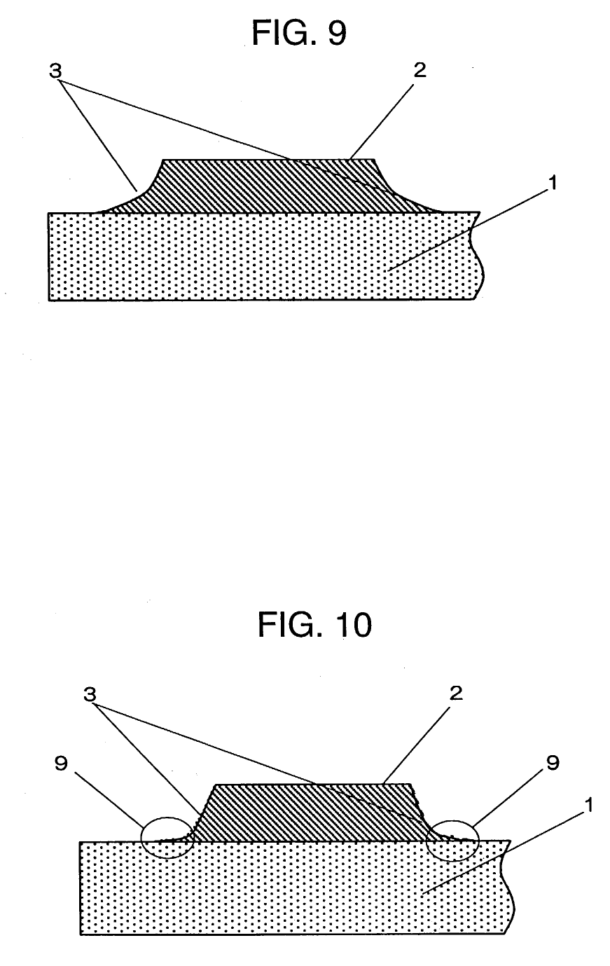

In FIG. 9, with respect to the orientation of the oblique sides, the angle made between the top surface of each piezoelectric body 2 and each side surface 3 is an obtuse angle. The side surfaces 3 are concave in shape. The same advantages can be obtained by inverting the orientation of the oblique sides of the piezoelectric bodies 2 (i.e., the angle made between the top surface of each piezoelectric body 2 and each side surface 3 is an acute angle) in a way not illustrated and firmly mounting the bodies.

The side surfaces 3 are formed by a method similar to the method used in the case of FIG. 7 except that a blade whose tip is shaped like the letter R is used.

In any case, ultrasonic waves reaching the side surfaces 3 attenuate as traveling toward the front ends of the oblique sides. The intensity becomes minimal at the front ends. Accordingly, reflected ultrasonic waves and parasitic waves are weak at the side surfaces 3. Interference with the propagating ultrasonic waves is less likely to occur.

FIG. 10 is a view showing that the corners 9 of the piezoelectric body at the portions where the side surfaces 3 of the piezoelectric bodies and the top surface of the nonpiezoelectric substrate are arc-shaped. Because of this arc-shaped form, the top surface of the nonpiezoelectric substrate is a tangential plane to the lower portion of each side surface 3 at the portions where the nonpiezoelectric substrate 1 and each piezoelectric body 2 are adhesively bonded together.

After firmly mounting the piezoelectric bodies 2 to the nonpiezoelectric substrate 1, they are cut using a blade having an R-shaped tip. Then, unwanted portions are removed. During the cutting, the height of the tip of the blade is made exactly coincident with the top surface of the nonpiezoelectric substrate 1. As a result, the side surfaces 3 are close in shape to the tip of the blade.

Thus, ultrasonic waves propagating from the piezoelectric bodies 2 to the nonpiezoelectric substrate 1 are not reflected at the corner portions 9 of the piezoelectric bodies. Hence, generation of parasitic waves due to reflection is suppressed.

[Embodiment 4]

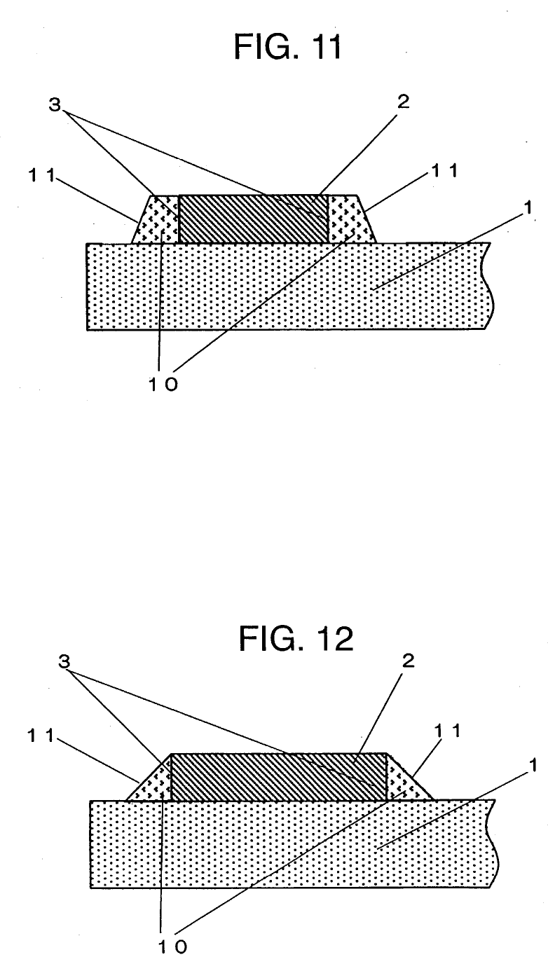

FIG. 11 is a cross-sectional view of the vicinities of piezoelectric bodies placed on a touch panel according to the present invention. The cross-sectional view is taken in the direction of propagation of ultrasonic waves. Piezoelectric bodies 2 and a thin metal sheet 10 having oblique sides are firmly mounted on a rectangular, nonconducting, nonpiezoelectric substrate 1. The thin metal sheet 10 has a height equivalent to that of each piezoelectric body 2 along the side surfaces 3 of the piezoelectric body intersecting with the propagating ultrasonic waves. The side surfaces 11 opposite to the piezoelectric body 2 are oblique sides. The orientation of the oblique sides is such that the angle made between the top surface of the piezoelectric body 2 and each side surface 11 is an obtuse angle. The method of arranging the nonpiezoelectric substrate 1 and piezoelectric bodies 2 of the touch panel according to the present invention is the same as the prior art method.

Thus, ultrasonic waves propagating to the thin metal sheet 10 are attenuated by the side surfaces 11. The intensity is minimal at the front ends of the oblique sides. Accordingly, the intensities of reflected waves and parasitic waves decrease at the side surfaces 3. Interference with the propagating ultrasonic waves is unlikely to occur.

The cross section of the thin metal sheet 10 of FIG. 11 is trapezoidal. Note that the invention is not limited to this shape. That is, if the cross section is triangular as shown in FIG. 12, similar advantages can be obtained.

The thin metal sheets 10 of the two examples described above are fabricated by melting solder, applying the melted solder to the nonpiezoelectric substrate 1 and to the side surfaces 3 of the piezoelectric body, and then hardening the solder. Since application of solder is a general method, the workability is good. A structure for suppressing reflected waves can be easily fabricated.

### INDUSTRIAL APPLICABILITY

As described thus far, in the present invention, structures for attenuating ultrasonic waves and suppressing reflection of ultrasonic waves at side surfaces of the piezoelectric body are provided on any one or both of two opposite side surfaces a and b intersecting with the propagation path for ultrasonic waves excited by the comb-like electrodes, the two side surfaces a and b being included in the side surfaces of the piezoelectric body.

A structure or structures capable of absorbing ultrasonic waves are firmly fixed to any one or both of the side surfaces a and b as structures for suppressing reflection of ultrasonic waves. In this way, ultrasonic waves are not reflected off the side surfaces of the piezoelectric body. Hence, parasitic waves are less easily produced.

The structure is formed from a sealant that seals the side surfaces of the piezoelectric body. Furthermore, the sealant is applied to the circuit board that is electrically connected with the comb-like electrodes. This is fabricated by firmly mounting the piezoelectric bodies to the nonpiezoelectric substrate, connecting the comb-like electrodes and the circuit board and firmly fixing them, and injecting a sealant into corner portions made by the side surfaces and the circuit board.

This improves the adhesive force with which the piezoelectric bodies are bonded to the circuit board and the strengths of electrical connected portions and the circuit board itself. At the same time, generation of reflected waves and parasitic waves is suppressed.

Furthermore, as structures of the side surfaces, those of the side surfaces of each piezoelectric body which intersect with propagating ultrasonic waves are formed as inclined surfaces. Alternatively, a thin metal sheet having a height equivalent to that of the piezoelectric body is firmly mounted to the side surfaces a and b. Of two opposite surfaces c and d of the thin metal sheet, the surface d opposite to the firmly mounted surface c with the piezoelectric body is formed as an inclined surface.

This can be formed by using a blade having an inclined surface or an R-shaped form at its tip during cutting of the side surfaces a, b, and d. As another method, a metal or metal oxide may be added to the side surfaces a, b, and d. That is, a metal is flame-sprayed onto the side surfaces or a metal brazing material or melted metal is applied to the side surfaces, and then the metal is hardened. Thus, it can be formed.

Where this thin metal sheet is not used, the intensity of ultrasonic waves at the front ends of the tilted surfaces of the side surfaces a and b is minimal. Generation of reflected waves and parasitic waves can be suppressed. The present fabrication method hardly affects the characteristics of the piezoelectric body. Furthermore, members for suppressing oscillations do not exist around the piezoelectric body. In consequence, the efficiency of the touch panel can be maintained high.

Where the thin metal sheet is used, generation of reflected waves and parasitic waves at the mounting interface between the piezoelectric body and the thin metal sheet is suppressed because of matching of acoustic impedance. Propagation of ultrasonic waves from the piezoelectric body to the thin metal sheet is carried out smoothly without involving generation of reflected waves or parasitic waves. The intensity of the propagating ultrasonic waves becomes minimal at the front ends of the inclined surface of the side surface d. Generation of reflected waves and parasitic waves can be suppressed. Use of such a thin metal sheet makes it easier to obtain a tilted structure than where the piezoelectric body is machined.

As a result, reflection of ultrasonic waves at the side surfaces of the piezoelectric body is suppressed. Generation of parasitic waves can be reduced. Accordingly, it is easy to provide control to detect whether there is a touch on the ultrasonic touch panel. Variations in the intensity of ultrasonic waves within the plane of the nonpiezoelectric substrate decrease. The output voltage is made constant. A touch panel having fewer malfunctions can be offered without adjusting the detection sensitivities of individual piezoelectric bodies.

I claim:

1. An ultrasonic touch panel comprising:
two piezoelectric bodies placed opposite to each other, each of said piezoelectric bodies being equipped with comb-like electrodes having a function of sending and receiving ultrasonic waves;
a nonpiezoelectric substrate having one surface on which said piezoelectric bodies are firmly mounted;
said comb-like electrodes being formed either on bottom surfaces of said piezoelectric bodies on which said nonpiezoelectric substrate is firmly mounted or on top surfaces of said piezoelectric bodies opposite to the bottom surfaces of said piezoelectric bodies;
side surfaces of each of said piezoelectric bodies including two opposite side surfaces a and b intersecting with propagation path for ultrasonic waves excited by said comb-like electrodes; and
a structure formed on any one or both of said side surfaces a and b for attenuating ultrasonic waves and suppressing reflection of ultrasonic waves at the side surface or surfaces.

2. An ultrasonic touch panel as set forth in claim 1, wherein a structure capable of absorbing ultrasonic waves is firmly mounted as said structure for suppressing reflection of the ultrasonic waves on the side surface or surfaces.

3. An ultrasonic touch panel as set forth in claim 2, wherein said structure is a resilient body.

4. An ultrasonic touch panel as set forth in claim 3, wherein a sealant for sealing said side surface or surfaces is applied as said resilient body.

5. An ultrasonic touch panel as set forth in claim 4, wherein said sealant is applied to any one or both of the side surfaces a and b placed opposite to each other, said side surface a being at a side of said piezoelectric bodies, said side surface b being opposite to said side surface a, and wherein the sealant applied to the side surface b is integrally applied to a circuit board electrically connected with said comb-like electrodes.

6. An ultrasonic touch panel as set forth in claim 5, wherein said circuit board is a flexible printed circuit and firmly mounted on the top surfaces of said piezoelectric bodies.

7. An ultrasonic touch panel as set forth in claim 3, wherein said resilient body is resilient rubber.

8. An ultrasonic touch panel as set forth in claim 1, wherein said side surfaces a and b are inclined surfaces.

9. An ultrasonic touch panel as set forth in claim 8, wherein each of said piezoelectric bodies has a cross-sectional shape that is a straight line at said side surfaces, and wherein an angle made between the top surface of each piezoelectric body and each of said side surfaces is an obtuse angle.

10. An ultrasonic touch panel as set forth in claim 8, wherein each of said piezoelectric bodies has a cross-sectional shape that is a concave curved line at said side surfaces, and wherein an angle made between the top surface of each piezoelectric body and each of said side surfaces is an obtuse angle.

11. An ultrasonic touch panel as set forth in claim 8, wherein each of said piezoelectric bodies has a cross-sectional shape that is a concave curved line at said side surfaces, and wherein an angle made between the top surface of each piezoelectric body and each of said side surfaces is an acute angle.

12. An ultrasonic touch panel as set forth in claim 8, wherein each of said piezoelectric bodies has a cross-sectional shape that is a straight line at said side surfaces, and wherein an angle made between the top surface of each piezoelectric body and each of said side surfaces is an acute angle.

13. An ultrasonic touch panel of any one of claims 8 to 12, wherein a corner portion made between each side surface and the bottom surface of each piezoelectric body is arc-shaped, and wherein the top surface of said nonpiezoelectric substrate is a tangential plane to lower portions of said side surfaces a and b at portions where said piezoelectric body and the top surface of said nonpiezoelectric substrate are adhesively bonded together.

14. An ultrasonic touch panel as set forth in claim 1, wherein a thin metal sheet having a height equivalent to height of each piezoelectric body and having two opposite surfaces c and d is firmly mounted to said side surfaces a and b, said surface c being firmly mounted to said piezoelectric bodies, and wherein the surface d of said two side surfaces a and b is an inclined surface.

15. An ultrasonic touch panel as set forth in claim 14, wherein said thin metal sheet has a cross-sectional shape that is a straight line at said side surface d, and wherein an angle made between the top surface of each piezoelectric body and the side surface is an obtuse angle.

16. An ultrasonic touch panel as set forth in claim 14, wherein said thin metal sheet has a cross-sectional shape that is a concave curved line at said side surface d, and wherein an angle made between the top surface of each piezoelectric body and the side surface is an obtuse angle.

17. An ultrasonic touch panel as set forth in claim 14, wherein said thin metal sheet has a cross-sectional shape that is a concave curved line at said side surface d, and wherein an angle made between the top surface of each piezoelectric body and the side surface is an acute angle.

18. An ultrasonic touch panel as set forth in claim 14, wherein said thin metal sheet has a cross-sectional shape that is a straight line at said side surface d, and wherein an angle made between the top surface of each piezoelectric body and the side surface is an acute angle.

19. An ultrasonic touch panel of any one of claims 14 to 18, wherein a corner portion made between the side surface d and the bottom surface of each piezoelectric body is arc-shaped, and wherein the top surface of said nonpiezoelectric substrate is a tangential plane to a lower portion of said side surface d of said thin metal sheet at portions where said thin metal sheet and the top surface of said nonpiezoelectric substrate are adhesively bonded together.

20. A method of fabricating an ultrasonic touch panel consisting two piezoelectric bodies placed opposite to each other, a nonpiezoelectric substrate, and a circuit board, each of said piezoelectric bodies being fitted with comb-like electrodes, said piezoelectric bodies being firmly mounted to one surface of said nonpiezoelectric substrate, said method comprising the step of:
applying a sealant to a side surface b of each of said piezoelectric bodies opposite to a side surface a of said piezoelectric body, said side surface a being located at a side of said piezoelectric body, said side surfaces a and b intersecting with propagation path for ultrasonic waves excited by said comb-like electrodes;
wherein said step of applying the sealant to the side surface b consists of firmly mounting said piezoelectric bodies to said nonpiezoelectric substrate, connecting said comb-like electrodes or terminal electrodes at the same potential as said comb-like electrodes with a pattern on said circuit board and firmly fixing them, and injecting the sealant into a corner portion made between said side surface b and said circuit board.

21. A method of fabricating an ultrasonic touch panel as set forth in claim 20, further comprising the step of applying the sealant to said side surface a to form the sealant on the side surface a.

22. A method of fabricating an ultrasonic touch panel consisting two piezoelectric bodies placed opposite to each other, and a nonpiezoelectric substrate, each of said piezoelectric bodies being fitted with comb-like electrodes, said piezoelectric bodies being firmly mounted to one surface of said nonpiezoelectric substrate, said method comprising the steps of:
obtaining a side surface structure in which side surfaces of said piezoelectric bodies intersecting with propagation path for ultrasonic waves excited by said comb-like electrodes are formed as inclined surfaces or firmly mounting a thin metal sheet having a height equivalent to height of said piezoelectric bodies to said side surfaces to thereby obtain a side surface structure in which side surfaces of said thin metal sheet opposite to firmly mounted surfaces at which said piezoelectric bodies is mounted to said piezoelectric bodies are formed as inclined surface; and
cutting said piezoelectric bodies or said thin metal sheet;
wherein said obtaining step and cutting step are carried out in one process.

23. A method of fabricating an ultrasonic touch panel as set forth in claim 22, wherein said side surface structure in which the cross-sectional shape at said side surfaces is a straight line is formed by cutting said piezoelectric bodies or said thin metal sheet by an oblique side of a blade having a height greater than the height of said piezoelectric bodies in a cross section at a tip portion of the blade.

24. A method of fabricating an ultrasonic touch panel as set forth in claim 22, wherein the side surface structure in which the cross-sectional shape at said side surfaces is a concave curved line is formed by cutting said piezoelectric body or said thin metal sheet by a blade having a tip of an R-shaped cross-sectional shape such that the tip of the blade is at a height equivalent to the bottom surface or surfaces of said piezoelectric bodies or said thin metal sheet.

25. A method of fabricating an ultrasonic touch panel consisting two piezoelectric bodies placed opposite to each other, and a nonpiezoelectric substrate, each of said piezoelectric bodies being fitted with comb-like electrodes, said piezoelectric bodies being firmly mounted to one surface of said nonpiezoelectric substrate, said method comprising the steps of:
obtaining a side surface structure in which side surfaces a and b of said piezoelectric bodies intersecting with propagation path for ultrasonic waves excited by said comb-like electrodes are formed as inclined surfaces or obtaining a side surface structure in which a side surface d opposite to a firmly mounted surface c mounted to each piezoelectric body is formed as an inclined surface, the two side surfaces c and d having a height equivalent to the height of each of said piezoelectric bodies firmly mounted to said side surfaces a and b;
causing said side surface structure to firmly mount said piezoelectric bodies or said thin metal sheet to said nonpiezoelectric substrate; and
adding a metal or metal compound to corner portions made between said side surfaces and said nonpiezoelectric substrate.

26. A method of fabricating an ultrasonic touch panel as set forth in claim 25, wherein said step of adding a metal or metal compound to said side surfaces is carried out by flame spraying.

27. A method of fabricating an ultrasonic touch panel as set forth in claim 25, wherein said step of adding a metal or metal compound to said side surfaces consists of applying a metal brazing material or melted metal and hardening said metal.
